(19) United States
(12) Patent Application Publication
(10) Pub. No.: US 2026/0247968 A1
(43) Pub. Date: Aug. 20, 2026

(54) ADAPTER AND SEMICONDUCTOR COOLING DEVICE

(71) Applicant: Mitsubishi Electric Corporation, Tokyo (JP)

(72) Inventor: Koichi USHIJIMA, Fukuoka (JP)

(73) Assignee: Mitsubishi Electric Corporation, Tokyo (JP)

(21) Appl. No.: 19/471,996

(22) PCT Filed: May 18, 2023
(86) PCT No.: PCT/JP2023/018599

§ 371 Date: Oct. 2, 2025

(51) Int. Cl. H10W 40/47; H10W 40/22

(52) U.S. Cl. CPC H10W 40/47; H10W 40/228

(57) ABSTRACT

A technique disclosed in the specification of the present application is a technique which can be easily applied to an existing cooling structure to improve a cooling effect. An adapter relating to a technique disclosed in the specification of the present application is an adapter provided to a flow path of a cooling medium for cooling a semiconductor element, wherein the semiconductor element is connected to a pin fin protruding to the flow path, the adapter includes a counterbore corresponding to a shape of the pin fin, and the adapter is attached to the pin fin so that at least a part of the pin fin is fitted to the counterbore in a side surface of the flow path.

### TECHNICAL FIELD

A technique disclosed in the specification of the present application relates to a technique of cooling a semiconductor element.

### BACKGROUND ART

In a semiconductor module, a semiconductor element as a heat generation source is bonded to a pin fin by soldering, for example, via an insulating material. Then, the semiconductor module is fixed to a jacket by a screw passing through a screw through hole of the semiconductor module and screwed into a screw hole of the jacket.

A cooling medium inlet and a cooling medium outlet for a cooling medium to flow in the jacket are provided to the jacket. In a flow path of the cooling medium formed of the cooling medium inlet and the cooling medium outlet, an opening in an upper surface is sealed by a lower surface (a surface in which the fin is formed) of the semiconductor module fixed to the jacket.

In a state where the semiconductor module and the jacket are connected, the semiconductor element in the semiconductor module is overlapped with the pin fin in a plan view. The cooling medium enters the jacket from the cooling medium inlet and flows to exit from the cooling medium outlet.

Heat generated from the semiconductor element is conducted to the cooling medium via the pin fin. Accordingly, the semiconductor element is cooled.

Herein, since a sidewall (side surface) of the flow path of the cooling medium has no unevenness and has low flow resistance, a flow of the cooling medium is concentrated and a flow speed increases even though the semiconductor element is not provided to a position overlapped in this region in a plan view. Then, a flow amount of the cooling medium decreases immediately below the semiconductor element, and such a state causes reduction of a heat radiation efficiency of the semiconductor element.

In contrast, disclosed is a technique of providing a convex shape to a sidewall of a flow path (for example, refer to Patent Document 1). Also performed are measures that a pin fin is disposed near a sidewall of the flow path to sufficiently reduce a gap with the sidewall, for example (for example, refer to Patent Document 2).

### PRIOR ART DOCUMENTS

### Patent Document(s)

Patent Document 1: International Publication No. 2022/163418
Patent Document 2: Japanese Patent Application Laid-Open No. 2013-120897

### SUMMARY

### Problem to be Solved by the Invention

However, according to the conventional technique, a structure itself of a pin fin or a cooler needs to be made. Thus, such a technique cannot be easily applied to an existing pin fin or cooler in some cases.

A technique disclosed in the specification of the present application therefore has been made in consideration of the above problems, and is a technique which can be easily applied to an existing cooling structure to improve a cooling effect.

### Means to Solve the Problem

An adapter according to a first aspect of a technique disclosed in the specification of the present application is an adapter provided to a flow path of a cooling medium for cooling a semiconductor element, wherein the semiconductor element is connected to a pin fin protruding to the flow path, the adapter includes a counterbore corresponding to a shape of the pin fin, and the adapter is attached to the pin fin so that at least a part of the pin fin is fitted to the counterbore in a side surface of the flow path.

### Effects of the Invention

According to at least the first aspect of the technique disclosed in the specification of the present application, the adapter can be easily attached to an existing cooling structure, and can improve a cooling effect.

These and other objects, features, aspects and advantages of the technique disclosed in the specification of the present application will become more apparent from the following detailed description when taken in conjunction with the accompanying diagrams.

### BRIEF DESCRIPTION OF DRAWINGS

FIG. 1 is a diagram illustrating an example of a structure of a semiconductor module including a pin fin and a structure of a jacket as a cooler.

FIG. 2 is a plan view illustrating the jacket and the semiconductor module in FIG. 1 connected to each other.

FIG. 3 is a diagram illustrating an example of a structure of an adapter provided to a semiconductor cooling device relating to an embodiment.

FIG. 4 is a diagram illustrating an example of a structure of a semiconductor module to which the adapter is mounted.

FIG. 5 is a plan view illustrating an example of a structure of the semiconductor module to which the adapter is mounted.

### DESCRIPTION OF EMBODIMENT(S)

Embodiments are described with reference to the appended diagrams hereinafter. Detailed features are also described for explaining a technique in the embodiment hereinafter; however, they are an exemplification, thus are not always necessary to be able to implement the embodiment.

The diagrams are schematically illustrated; thus, omission or simplification of the configuration is performed on the diagrams for explanatory convenience. A mutual relationship of sizes and positions of configurations respectively illustrated in the different diagrams is not necessarily illustrated accurately, but may be appropriately changed. A hatching may be drawn in a plane view, for example, as well as a cross-sectional view to easily understand contents of the embodiment.

In the description hereinafter, the same reference numerals will be assigned to the similar constituent elements in the diagrams, and the constituent elements having the same reference numeral have the same name and function. Accordingly, the detailed description on them may be omitted to avoid a repetition in some cases.

In the description in the specification of the present application, when there is a description of “comprising”, “including”, or “having” a certain constituent element, such a description does not indicate an exclusive expression excluding the other constituent element unless otherwise noted.

In the description in the specification of the present application, even when ordinal numbers such as “first” or “second” are stated, the terms are used to facilitate understanding of embodiments, and therefore, the embodiments are not limited to an order which may be caused by the ordinal numbers.

In the description in the specification of the present application, even when terms indicating a specific position and direction such as “upper”, “lower”, “left”, “right”, “side”, “bottom”, “front” or “rear” are stated, the terms are used to facilitate understanding contents of embodiments for convenience, and therefore, irrelevant to positions or directions in practical implementation.

In the description in the specification of the present application, when “upper surface of” or “lower surface of”, for example, is described, these include not only an upper surface itself or a lower surface itself of a target constituent element but also a state where the other constituent element is formed on an upper surface or a lower surface of a target constituent element. That is to say, “B provided to an upper surface of A”, for example, does not eliminate a configuration of intervention of the other constituent element “C” between A and B.

### Embodiment

An adapter relating to the present embodiment is described hereinafter. A technique relating to a configuration of a semiconductor device which the inventor knows is described first for convenience of description.

### Configuration of Adapter

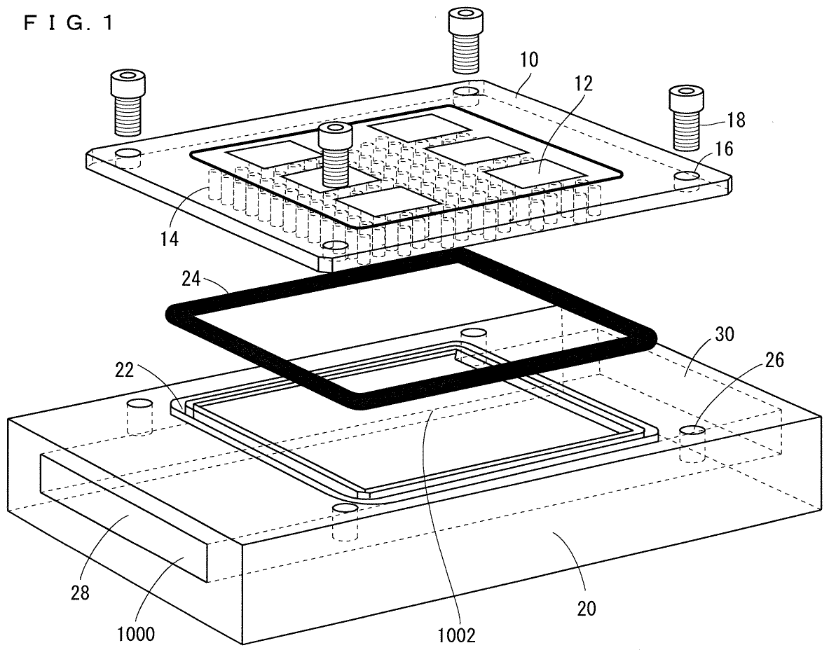

FIG. 1 is a diagram illustrating an example of a structure of a semiconductor module including a pin fin and a structure of a jacket as a cooler. The semiconductor module and the jacket are also collectively referred to as a semiconductor cooling device. As exemplified in FIG. 1, in a semiconductor module 10, a semiconductor element 12 as a heat generation source is bonded to a pin fin 14 by soldering, for example, via an insulating material. The pin fin 14 is provided to a position including a position overlapped with the semiconductor element 12 in a plan view, and protrudes on a lower surface of the semiconductor module 10. The semiconductor element is a metal-oxide-semiconductor field-effect transistor (that is to say, MOSFET) or an insulated gate bipolar transistor (that is to say, IGBT), for example.

The semiconductor module 10 is fixed to a jacket 20 by a screw 18 passing through a screw through hole 16 of the semiconductor module 10 and screwed into a screw hole 26 of the jacket 20.

An O ring insertion groove 22 is provided to a surface of the jacket 20 connected to the semiconductor module 10. Also provided is an opening 1002 surrounded by the O ring insertion groove 22 so that a flow path of a cooling medium is exposed from the opening 1002 and access to the flow path can be made. Then, the jacket 20 and the semiconductor module 10 are connected while an O ring 24 is inserted into the O ring insertion groove 22.

A cooling medium inlet 28 and a cooling medium outlet 30 for the cooling medium to flow in the jacket 20 are provided to the jacket 20. In a flow path 1000 of the cooling medium formed of the cooling medium inlet 28 and the cooling medium outlet 30, the opening 1002 in an upper surface is sealed by a lower surface (a surface in which the fin is formed) of the semiconductor module 10 fixed to the jacket 20.

FIG. 2 is a plan view illustrating the jacket 20 and the semiconductor module 10 in FIG. 1 connected to each other. An arrow indicates a direction in which the cooling medium flows.

As illustrated in FIG. 2, in the state where the semiconductor module 10 and the jacket 20 are connected, the semiconductor element 12 in the semiconductor module 10 is overlapped with the pin fin 14 in a plan view. The cooling medium enters the jacket 20 from the cooling medium inlet 28 and flows to exit from the cooling medium outlet 30.

Heat generated from the semiconductor element 12 is conducted to the cooling medium via the pin fin 14 inserted into the flow path. Accordingly, the semiconductor element 12 is cooled.

Herein, since an a region and a b region in FIG. 2 corresponding to a sidewall (side surface) of the flow path 1000 of the cooling medium has no unevenness and has low flow resistance, a flow of the cooling medium is concentrated and a flow speed increases even though the semiconductor element 12 is not provided to a position overlapped in this region in a plan view. Then, a flow amount of the cooling medium decreases immediately below the semiconductor element 12, and such a state causes reduction of a heat radiation efficiency of the semiconductor element 12.

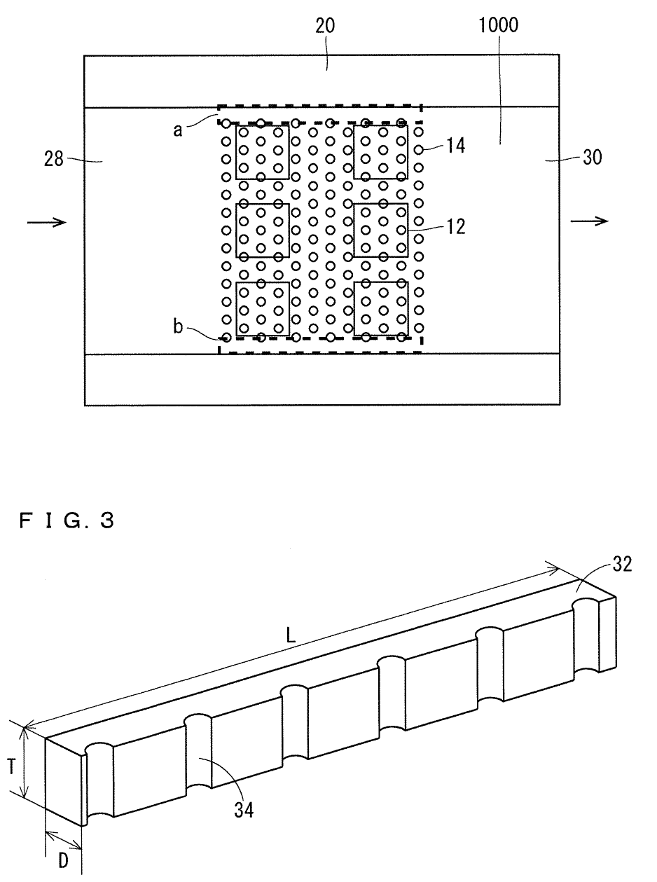

FIG. 3 is a diagram illustrating an example of a structure of an adapter provided to a semiconductor cooling device relating to the present embodiment.

As exemplified in FIG. 3, an adapter 32 is a rectangular parallelepiped having a height T, a thickness D, and a length L, and the height T is substantially equal to a pin length of the pin fin 14. Accordingly, the adapter 32 is easily positioned in a height direction. However, a shape of the adapter 32 is not limited to the rectangular parallelepiped. A counterbore 34 is formed in a side surface of the adapter 32. As illustrated in FIG. 3, the counterbore 34 may have an inner surface shape (a shape to which the pin fin 14 can be fitted) corresponding to a shape of the pin fin 14.

The thickness D of the adapter 32 is substantially equal to a distance from the sidewall of the flow path 1000 of the cooling medium to the pin fin 14 in the state where the semiconductor module 10 and the jacket 20 are connected.

The length L of the adapter 32 is set to cover an area where the semiconductor element 12 is disposed in the state where the semiconductor module 10 and the jacket 20 are connected.

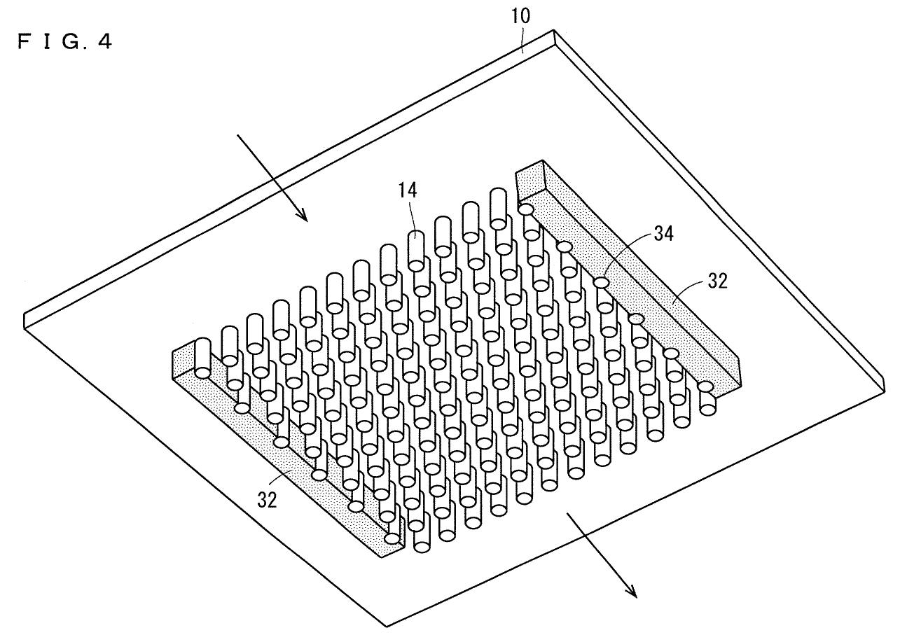

FIG. 4 is a diagram illustrating an example of a structure of the semiconductor module to which the adapter is mounted. An arrow indicates a direction in which the cooling medium flows. As exemplified in FIG. 4, the adapter 32 is attached to the pin fin 14 on both sidewall sides of the flow path of the cooling medium. The adapter 32 is attached in a state where the counterbore 34 of the adapter 32 has contact with a side surface of the pin fin 14 (a part of the pin fin 14 is fitted to the inner surface of the counterbore 34 so that half a circumferential direction of the pin fin 14 is covered, for example).

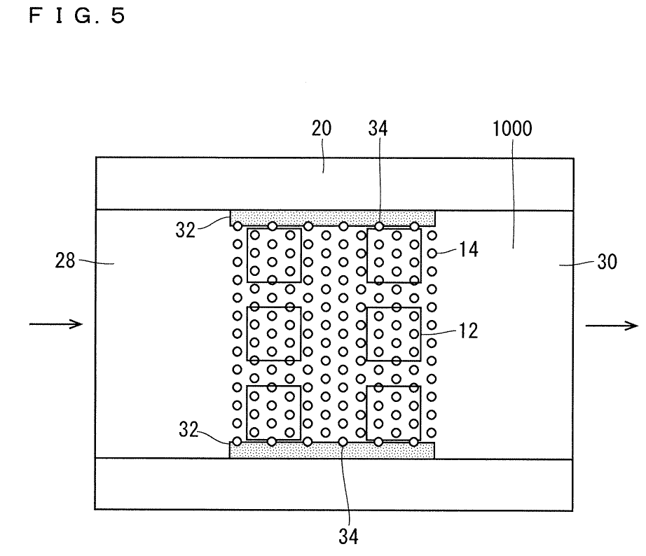

FIG. 5 is a plan view illustrating an example of a structure of the semiconductor module to which the adapter is mounted. An arrow indicates a direction in which the cooling medium flows. As exemplified in FIG. 5, the adapter 32 is attached on both sidewall sides of the flow path of the cooling medium. The length L of the adapter 32 is set to cover the area where the semiconductor element 12 is arranged, that is to say, to locate the adapter 32 on a sidewall side of the flow path 1000 in a position where the semiconductor element 12 is disposed.

In FIG. 4 and FIG. 5, the adapter 32 is provided on both sidewall sides, but may also be provided to only one sidewall side.

Since the adapter 32 is attached as illustrated in FIG. 4 and FIG. 5, concentration of the cooling medium to the sidewall side of the flow path 1000 on which the pin fin 14 is not provided can be suppressed. Since the length L of the adapter 32 is set to cover the whole area where the semiconductor element 12 is disposed, pressure loss of the cooling medium caused by sharp reduction of the flow path 1000 of the cooling medium in width can be reduced. This becomes effective by dividing and locating the adapter 32 for each phase in a large-size inverter module having UVW phases, for example.

As illustrated in FIG. 3, the adapter 32 includes the counterbore 34 having a diameter equal to or smaller than a diameter of the pin fin 14 having a columnar shape and the corresponding shape as the pin fin 14 along the sidewall of the flow path of the cooling medium. However, when the pin fin 14 does not have the columnar shape, the shape of the counterbore 34 can have a shape conforming to an outer shape of the pin 14. A depth of the counterbore 34 can be deep enough to embed half the circumferential direction of the pin fin 14.

As illustrated in FIG. 3, the counterbore 34 can be formed along a direction of the length L of the adapter 32 so that the number and interval thereof are the same as those of the pin fins 14.

As illustrated in FIG. 4, when the pin fin 14 is inserted into the counterbore 34 of the adapter 32, the adapter 32 is positioned in a flow direction of the cooling medium. Furthermore, when the semiconductor module 10 to which the adapter 32 is attached is inserted into the jacket 20, the pin fin 14 and the adapter 32 are positioned in an up-down direction of the flow path of the cooling medium and fixed.

Accordingly, a structure needs not be changed (for example, an attachment jig is additionally provided) in fixing the adapter 32. In FIG. 4, two adapters 32 in total are attached one by one to wall surface sides on both sides in parallel to the flow direction of the cooling medium.

The pin fin 14 located on the sidewall side of the flow path is located adjacent to the adapter 32 in place of the sidewall by the adapter 32 fixed in the flow path of the cooling medium. Then, flow resistance increases in the adapter 32, and concentration of the flow amount in the sidewall side of the flow path can be avoided; thus, the flow amount of the cooling medium immediately below the semiconductor element 12 resultingly increases. Thus, cooling performance can be improved without significantly changing an existing cooling structure.

A material of the adapter 32 is resin, metal, or ceramic, for example, and is selected in accordance with a temperature in use or necessary durability.

### Effects Generated by Embodiments Described Above

Examples of effects generated by the above embodiments are described next. It should be noted that, in the following description, the effects are described based on the specific configurations exemplified in the above embodiments, however, other specific configurations may be applied in place of the configurations illustrated in the specification of the present application, within the scope of producing the similar effects. That is to say, in the description hereinafter, only one of the associated specific configurations is described as a representative in some cases, however, the specific configuration described as the representative may be replaced with the other associated specific configuration.

According to the embodiment described above, the adapter is the adapter 32 provided to the flow path 1000 of the cooling medium for cooling the semiconductor element 12. Herein, the semiconductor element 12 is connected to the pin fin 14 protruding to the flow path 1000. The adapter 32 includes the counterbore 34 corresponding to the shape of the pin fin 14. The adapter 32 is attached to the pin fin 14 so that at least a part of the pin fin 14 is fitted to the counterbore 34 in the side surface of the flow path 1000.

According to such a configuration, the adapter can be easily attached to an existing cooling structure (the pin fin 14), and a cooling effect can be improved. Since the counterbore 34 is included, the adapter 32 can be easily positioned with respect to the pin fin 14 and further in the flow path of the cooling medium.

Even in the case where the other configurations other than the configurations illustrated in the specification of the present application is appropriately added to the configuration described above, that is to say, the other configurations other than the configurations illustrated in the specification of the present application, which are not referred to as configurations described above are appropriately added, the similar effects can be produced.

According to the embodiment described above, the adapter has the same height as that of the pin fin 14 while being attached to the pin fin 14. According to such a configuration, the adapter 32 can be easily positioned in the height direction based on the pin fin 14.

According to the embodiment described above, the adapter is disposed to cover the sidewall side of the flow path 1000 in the position where the semiconductor element 12 is disposed while being attached to the pin fin 14. According to such a configuration, pressure loss of the cooling medium caused by sharp reduction of the flow path 1000 of the cooling medium in width can be reduced.

According to the embodiment described above, the semiconductor cooling device includes the semiconductor module 10 to which the semiconductor element 12 is mounted and the jacket 20 for cooling the semiconductor element 12. Herein, the semiconductor module 10 includes the pin fin 14 provided to the lower surface overlapped with the semiconductor element 12 in a plan view and the adapter 32 attachable to the pin fin 14. The jacket 20 includes the flow path 1000 of the cooling medium for cooling the semiconductor element 12 and the opening 1002 provided to be able to have access to the flow path 1000. The semiconductor module 10 insets the pin fin 14 into the flow path 1000 via the opening 1002. The adapter 32 includes the counterbore 34 corresponding to the shape of the pin fin 14. The adapter 32 is attached to the pin fin 14 so that at least a part of the pin fin 14 is fitted to the counterbore 34 in the side surface of the flow path 1000, thereby being fixed to the flow path 1000.

According to such a configuration, since the adapter 32 is attached to the pin fin 14, increase of the flow amount of the cooling medium on the sidewall side of the flow path 1000 is suppressed, and the cooling effect can be improved. Since the counterbore 34 is included, the adapter 32 can be easily positioned with respect to the pin fin 14 and further in the flow path of the cooling medium.

According to the embodiment described above, the semiconductor module 10 inserts the pin fin into the flow path 1000 via the opening 1002 while the adapter 32 is attached to the pin fin 14. According to such a configuration, the semiconductor module 10 and the jacket 20 are combined and the adapter 32 can be positioned while the adapter 32 is positioned with respect to the pin fin 14.

### Modification Example of Embodiment Described Above

In the embodiments described above, material properties, materials, dimensions, shapes, relative arrangement relations, conditions for implementation, and so forth for the respective constituent elements may be described; however, these represent a mere example in all aspects, and are not limited to the description thereof.

Accordingly, it is understood that numerous unexemplified modifications, variations, and equivalents can be devised within the scope of the technique disclosed in the specification of the present application. For example, a case where at least one constituent element is deformed includes a case where the constituent element is added or omitted.

In at least one embodiment described above, when names of materials are stated unless otherwise specified, other additives, for example, are included in the materials such as alloys, so far as consistent with the embodiments.

When it is described that “a” constituent element is included in the embodiment described above, “one or more” constituent elements may be included so far as consistent with the embodiments.

Further, individual constituent elements are conceptual units. Thus, within the range of the technique disclosed in the specification of the present application, one constituent element may include multiple structures, one constituent element may correspond to part of some structure, and multiple constituent elements may be included in one structure.

Each constituent element includes a structure having a different configuration or a different shape as long as the structure of the different configuration or the different shape achieves the same function.

What has been described in the specification of the present application is referred for all purposes regarding the present technique. It is thus not an admission that any of the descriptions provided herein are conventional techniques.

### EXPLANATION OF REFERENCE SIGNS

10 semiconductor module, 12 semiconductor element, 14 pin fin, 16 screw through hole, 18 screw, 20 jacket, 22 O ring insertion groove, 24 O ring, 26 screw hole, 28 cooling medium inlet, 30 cooling medium outlet, 32 adapter, 34 counterbore, 1000 flow path, 1002 opening, D thickness, T height.

1. An adapter provided to a flow path of a cooling medium for cooling a semiconductor element, wherein
the semiconductor element is connected to a pin fin protruding to the flow path,
the adapter includes a counterbore corresponding to a shape of the pin fin, and
the adapter is attached to the pin fin so that at least a part of the pin fin is fitted to the counterbore in a side surface of the flow path.

2. The adapter according to claim 1, wherein
the adapter has a height equal to a height of the pin fin in a state of being attached to the pin fin.

3. The adapter according to claim 1-or 2, wherein
the adapter is disposed to cover a sidewall side of the flow path in a position where the semiconductor element is disposed in a state of being attached to the pin fin.

4. A semiconductor cooling device, comprising:
a semiconductor module to which a semiconductor element is mounted; and
a jacket for cooling the semiconductor element, wherein
the semiconductor module includes:
a pin fin provided to a lower surface overlapped with the semiconductor element in a plan view; and
an adapter attachable to the pin fin,
the jacket includes:
a flow path of a cooling medium for cooling the semiconductor element; and
an opening provided to be able to have access to the flow path,
the semiconductor module inserts the pin fin into the flow path via the opening,
the adapter includes a counterbore corresponding to a shape of the pin fin, and
the adapter is attached to the pin fin so that at least a part of the pin fin is fitted to the counterbore in a side surface of the flow path, thereby being fixed to the flow path.

5. The semiconductor cooling device according to claim 4, wherein
the semiconductor module inserts the pin fin into the flow path via the opening while the adapter is attached to the pin fin.

6. The adapter according to claim 2, wherein
the adapter is disposed to cover a sidewall side of the flow path in a position where the semiconductor element is disposed in a state of being attached to the pin fin.
